(19) United States
(12) Patent Application Publication
(10) Pub. No.: US 2024/0258359 A1
(43) Pub. Date: Aug. 1, 2024

(54) FRONTSIDE-ILLUMINATED IMAGE SENSOR

(71) Applicant: ENKRIS SEMICONDUCTOR, INC., Suzhou, Jiangsu (CN)

(72) Inventors: Yuchao CHEN, Suzhou, Jiangsu (CN); Kai CHENG, Suzhou, Jiangsu (CN)

(73) Assignee: ENKRIS SEMICONDUCTOR, INC., Suzhou, Jiangsu (CN)

(21) Appl. No.: 18/560,919

(22) PCT Filed: Jun. 18, 2021
(86) PCT No.: PCT/CN2021/101073

§ 371 Date: Nov. 14, 2023

(51) Int. Cl. H01L 27/146

(52) U.S. Cl. CPC H01L 27/14645; H01L 27/14621; H01L 27/14623; H01L 27/14627; H01L 27/14636

(57) ABSTRACT

The present disclosure provides a frontside-illuminated image sensor, including: a base, a photosensitive unit, a color filter unit and a lens structure. The base has charge storage regions. The photosensitive unit is on the base, the photosensitive unit includes photosensitive layers for different colors, and one of the photosensitive layers is electrically connected to one of the charge storage regions. The color filter unit is at a side of the photosensitive unit away from the base, the color filter unit includes color filter layers for different colors, and one of the color filter layers corresponds to one of the photosensitive layers. The lens structure is at a side of the color filter unit away from the base.

### CROSS REFERENCE TO RELATED APPLICATIONS

This application is a US National Phase of a PCT Application No. PCT/CN2021/101073 filed on Jun. 18, 2021, the entire contents of which are incorporated herein by reference in their entireties.

### TECHNICAL FIELD

The present disclosure relates to the field of semiconductor technology, and in particular to a frontside-illuminated image sensor.

### BACKGROUND

The image sensor, by using the photoelectric conversion function of photoelectronic devices, converts a light image on a photosensitive surface into an electrical signal that is proportional to the light image. Compared with photosensitive elements of “point” light sources such as photodiodes and phototransistors, the image sensor is a functional device that divides the light image on the photosensitive surface into many small units and converts these small units into usable electrical signals. Image sensors are divided into plumbicon and solid-state image sensor. Compared with plumbicon, the solid-state image sensor has the characteristics of small size, light weight, high integration, high image resolution, low power consumption, long service life, low price, etc. Therefore, the solid-state image sensor has been widely used in various industries.

Currently, most of the image sensors are backside-illuminated CMOS structures. The shortcomings of the backside-illuminated image sensor are that: first, the photodiode and electrical interconnection structure for photoelectric conversion need to be manufactured on the front side of the silicon wafer, and the filter structure and lens are manufactured on the back side of the silicon wafer, the process is complex, and the photodiode on the front side need to be aligned with the filter structure and lens on the back side, which results that a yield of the backside-illuminated image sensor is lower: second, the photodiode occupies a large area, which makes the space for the charge storage and storage capacitor more limited, and increases the design difficulty for High-Dynamic Range (HDR) performance and capacitor design for Global Shutter: third, when light propagates to the photodiode in the silicon chip, there is a large interference, a deep trench isolation structure needs to be made to isolate the light propagated to adjacent photodiodes, and the process is complicated.

In addition, in photodiodes, as a requirement for dynamic range is increased and applications for global shutter become more popular, the requirements for larger full well capacity and larger storage capacitance are getting higher and higher. The current solutions on the market mainly focus on redesigning the photodiode and storage capacitor and modifying the circuit to match them. These solutions do not substantially change the total storage space and increase the difficulty of circuit design. The requirement of back-illumination further increases the difficulty of the process.

### SUMMARY

The purpose of the present disclosure is to provide a frontside-illuminated image sensor to solve the deficiencies in related technologies.

In order to achieve the above object, the present disclosure provides a frontside-illuminated image sensor, including:
a base having charge storage regions;
a photosensitive unit above the base, where the photosensitive unit includes photosensitive layers for different colors, and one of the photosensitive layers is electrically connected to one of the charge storage regions;
a color filter unit at a side of the photosensitive unit away from the base, where the color filter unit includes color filter layers for different colors, and one of the color filter layers corresponds to one of the photosensitive layers; and
a lens structure at a side of the color filter unit away from the base.

Optionally, the photosensitive unit includes a red-light photosensitive layer, a green-light photosensitive layer and a blue ling photosensitive layer, and the materials of the red-light photosensitive layer, the green-light photosensitive layer and the blue-light photosensitive layer are all GaN-based materials containing different proportion for In, to generate photosensitive charges based on wavelengths of received light and store the photosensitive charges in a corresponding charge storage region or not generate photosensitive charges based on the wavelengths of the received light.

Optionally, a range of a proportion for In in the red-light photosensitive layer is from 0.4 to 0.6:
a range of a proportion for In in the green-light photosensitive layer is from 0.2 to 0.3; and
a range of a proportion for In in the blue-light photosensitive layer is from 0.01 to 0.1.

Optionally, transistors are provided on the base, and a source region or a drain region of at least one of the transistors is one of the charge storage regions: there is a metal interconnection layer between the base and the photosensitive unit, and a metal interconnection structure of the metal interconnection layer layers is used to electrically connect to the transistors.

Optionally, there is conductive plug in the metal interconnection layer, a first end of the conductive plug is connected to the one of the photosensitive layers, and a second end is electrically connected to one of the charge storage regions.

Optionally, the first end of the conductive plug is connected to a sidewall of the one of the photosensitive layers.

Optionally, there is a first light-shielding structure between the photosensitive layers for different colors, and/or there is a second light-shielding structure between the color filter layers for different colors.

Optionally, the material of the first light-shielding structure is metal molybdenum, metal molybdenum alloy, metal aluminum or metal aluminum alloy; and/or the second light-shielding structure is a black matrix.

Optionally, there is a first light-shielding structure between the photosensitive layers for different colors, and the first light-shielding structure is further between the color filter layers for different colors.

Optionally, the material of the first light-shielding structure is metal molybdenum, an alloy of metal molybdenum, metal aluminum, an alloy of metal aluminum, or a black matrix.

### BRIEF DESCRIPTION OF DRAWINGS

FIG. 1 is a schematic cross-sectional structural diagram of a frontside-illuminated image sensor according to a first embodiment of the present discourse;

FIG. 2 is a schematic cross-sectional structural diagram of a frontside-illuminated image sensor according to a second embodiment of the present disclosure:

FIG. 3 is a schematic cross-sectional structural diagram of a frontside-illuminated image sensor according to a third embodiment of the present disclosure:

FIG. 4 is a schematic cross-sectional structural diagram of a frontside-illuminated image sensor according to a fourth embodiment of the present disclosure.

For the convenience of understanding the present disclosure, all reference numerals appearing in the present disclosure are listed below.
Frontside-illuminated image sensor 1,2, 3, 4
Base 10
Charge storage region 101
Photosensitive unit 11
Red-light photosensitive layer 11a
Green-light photosensitive layer 11b
Blue-light photosensitive layer 11c
Color filter unit 12
Red-light filter layer 12a
Green-light filter layer 12b
Blue-light filter layer 11c
Lens structure 13
First light-shielding structure 111
Second light-shielding structure 121
Transistor 102
Metal interconnection layer 14
Metal interconnection structure 141
Conductive plug 142

### DETAILED DESCRIPTION

In order to make the above-mentioned objects, features and advantages of the present disclosure more obvious and understandable, embodiments of the present disclosure will be described in detail below with reference to the accompanying drawings.

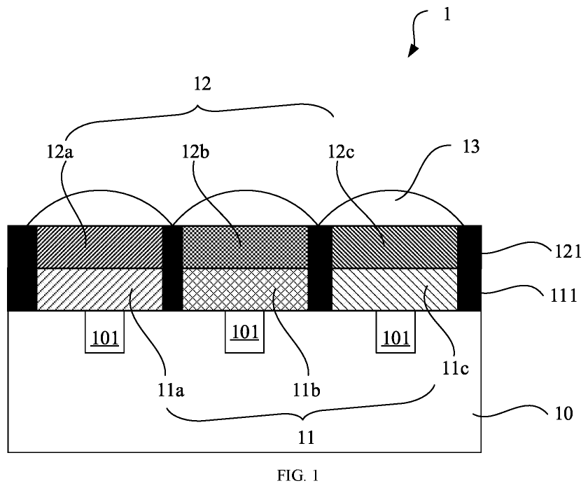

FIG. 1 is a schematic cross-sectional structural diagram of a frontside-illuminated image sensor according to a first embodiment of the present disclosure.

Referring to FIG. 1, a frontside-illuminated image sensor 1 includes:
a base 10 having a plurality of charge storage regions 101:
a photosensitive unit 11 on the base 10: where the photosensitive unit 11 includes photosensitive layers for different colors, and one photosensitive layer is electrically connected to one charge storage region 101:
a color filter unit 12 at a side of the photosensitive unit 11 away from the base 10; where the color filter unit 12 includes color filter layers for different colors, and one color filter layer corresponds to one photosensitive layer; and
a lens structure 13 at a side of the color filter unit 12 away from the base 10.

The base 10 may be a single crystal silicon substrate. The charge storage region 101 may be a floating diffusion (FD) region. For example, an n-type lightly doped region formed in a p-type well may be used as a floating diffusion region.

The photosensitive unit 11 includes a red-light photosensitive layer 11a, a green-light photosensitive layer 11b and a blue-light photosensitive layer 11c. The materials of the red-light photosensitive layer 11a, the green-light photosensitive layer 11b and the blue-light photosensitive layer 11c are all GaN-based materials containing different proportions for In element to make the photosensitive layers generate or not generate photosensitive charges according to different wavelengths of the received light and the generated photosensitive charges are stored in the corresponding charge storage region 101.

The proportion of In component of the red-light photosensitive layer 11a may be greater than the proportion of In component of the green-light photosensitive layer 11b, and the proportion of In component of the green-light photosensitive layer 11b may be greater than the proportion of In component of the blue-light photosensitive layer 11c.

In this embodiment, as shown in FIG. 1, the photosensitive unit 11 is formed on the base 10. Before the epitaxial growth of the red-light photosensitive layer 11a, the green-light photosensitive layer 11b and the blue-light photosensitive layer 11c, a mask layer may be formed on the base 10. In an example, firstly, multiple first openings are formed in the mask layer, where the multiple first openings respectively corresponds to the red-light photosensitive layer 11a of each photosensitive unit 11; and the red-light photosensitive layer 11a is epitaxially grown inside each first opening. Then, multiple second openings are formed in the mask layer, where the multiple second openings respectively corresponds to the green-light photosensitive layer 11b of each photosensitive unit 11; and the green-light photosensitive layer 11b is epitaxially grown inside each second opening. Finally, multiple third openings are formed in the mask layer, where the multiple third openings respectively corresponds to the blue-light photosensitive layer 11c of each photo sensitive unit 11; and the blue-light photosensitive layer 11c is epitaxially grown inside each third opening. Sizes of the first opening, the second opening and the third opening may be controlled, for example, the sizes may be the same. When the red-light photosensitive layer 11a, the green-light photosensitive layer 11b and the blue-light photosensitive layer 11c are epitaxially grown respectively, the proportion for the In element may be different in the red-light photosensitive layer 11a, the green-light photosensitive layer 11b and the blue-light photosensitive layer 11c respectively, by controlling conditions of processes different.

In another example, the mask layer has three openings corresponding to one photosensitive unit 11, and the red-light photosensitive layer 11a, the green-light photosensitive layer 11b and the blue-light photosensitive layer 11c correspond to one opening respectively. The opening corresponding to the red-light photosensitive layer 11a is smaller than the opening corresponding to the green-light photosensitive layer 11b, and the opening corresponding to the green-light photosensitive layer 11b is smaller than the opening corresponding to the blue-light photosensitive layer 11c. The sizes of the openings are different, and the flow rates of the reaction gases in each opening are different when the photosensitive layers are grown, so the doping rates of the In element and the Ga element are different, that is, the doping efficiency of the In element in each opening is different, which results in that the proportions of In element in grown photosensitive layers are different. Specifically, the smaller the opening, the faster the growth rate of the basic material GaN of the photosensitive layer in the opening is, the better the selectivity of doping for In element is, and the doping rate of In element is greater than the doping rate of Ga element. Therefore, the smaller the opening, the higher the proportion of In element in the photosensitive layer InGaN is.

In the red-light photosensitive layer 11a, the proportion range of In component in the red-light photosensitive layer 11a may be from 0.4 to 0.6, and the range of the wavelength for the light required to generate the photosensitive current may be from 400 nm to 720 nm.

In the green-light photosensitive layer 11b, the proportion range of In component may be from 0.2 to 0.3, and the range of the wavelength for the light required to generate photosensitive current may be from 400 nm to 600 nm.

In the blue-light photosensitive layer 11c, the proportion range of In component may be from 0.01 to 0.1, and the range of the wavelength for the light required to generate photosensitive current may be from 400 nm to 500 nm.

It should be noted that the proportion of In composition in the red-light photosensitive layer 11a refers to the percentage of the amount of substance of In element to the sum of the amounts of substance of all positively charged elements in the red-light photosensitive layer 11a. For example, the material of the red-light photosensitive layer 11a is InGaN, and the proportion of In component refers to the percentage for the amount of substance for In to the sum of the amount of substance for In and Ga: the material of the red-light photosensitive layer 11a is InAlGaN. The proportion of In component refers to the percentage of the amount of substance for In to the sum of the amounts of substance for In, Al and Ga.

The proportion of In component in the green-light photosensitive layer 11b refers to the percentage of the amount of substance for In in the sum of the amounts of substance for all elements with positive charge in the green-light photosensitive layer 11b.

The proportion of In component in the blue-light photosensitive layer 11c refers to the percentage of the amount of substance for In in the sum of the amounts of substance for all elements with positive charge in the blue-light photosensitive layer 11c.

In addition, in this embodiment, each numeric range includes the end-point value.

Since a red-light filter layer 12a is above the red-light photosensitive layer 11a, a green-light color filter layer 12b is above the green-light photosensitive layer 11b, and a blue-light color filter layer 11c is above the blue-light photosensitive layer 11c. Therefore, if illuminated by blue-light, only the blue-light photosensitive layer 11c may generate photosensitive electrical signals. If illuminated by green-light, only the green-light photosensitive layer 11b may generate photosensitive electrical signals. If illuminated by red-light, only the red-light photosensitive layer 11a may generate photosensitive electrical signals.

In this embodiment, the red-light photosensitive layer 11a, and/or the green-light photosensitive layer 11b, and/or the blue-light photosensitive layer 11c is single layer structure. In other embodiments, the red-light photosensitive layer 11a, and/or green-light photosensitive layer 11b, and/or blue-light photosensitive layer 11c may also be a laminated structure. For example, the red-light photosensitive layer 11a, and/or green-light photosensitive layer 11b, and/or blue-light photosensitive layer 11c is a multi-quantum well layer including two barrier layers and a potential well layer sandwiched between the two barrier layers.

In this embodiment, correspondingly, the color filter unit 12 includes the red-light color filter layer 12a, the green-light color filter layer 12b and the blue-light color filter layer 11c.

The lens structure 13 includes a plurality of lenses, and one lens is disposed above the color filter layer with each color.

In addition, in this embodiment, there is a first light-shielding structure 111 between the photosensitive layers for different colors, and a second light-shielding structure 121 between the color filter layers for different colors. Before epitaxially growing the red-light photosensitive layer 11a, the green-light photosensitive layer 11b and the blue-light photosensitive layer 11c on the base 10, a plurality of first light-shielding structure 111 may be formed above the base 10).

The material of the first light-shielding structure 111 may be metal molybdenum, an alloy of metal molybdenum, metal aluminum or an alloy of metal aluminum, and the second light-shielding structure 121 may be a black matrix. In order to prevent interference between adjacent photosensitive layers, an insulating side wall (spacer) may be provided on a side wall of the first light-shielding structure 111. The material of the insulating sidewall is, for example, silicon nitride or silicon dioxide.

In this embodiment, (1) the image sensor is a frontside-illuminated image sensor 1, which can avoid making a structure on the back side of the base 10, thereby the alignment of the front structure and the back structure is avoided, and a simple process and a high yield are achieved: (2) one photosensitive layer is electrically connected to a charge storage region 101, which greatly reduces interference caused during light propagation.

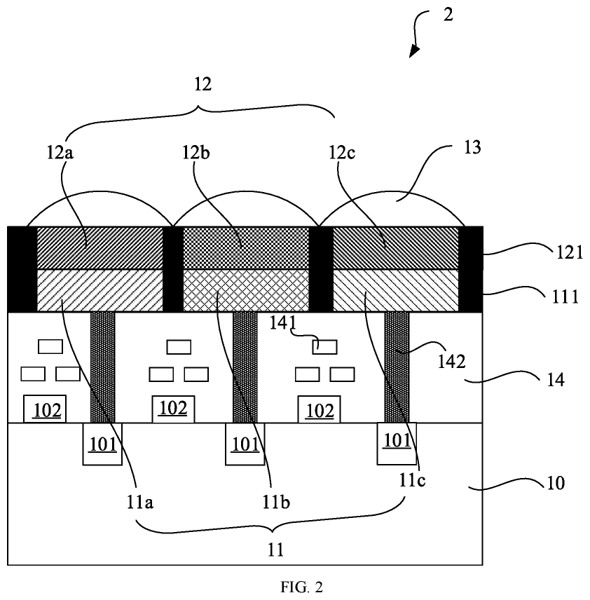

FIG. 2 is a schematic cross-sectional structural diagram of a frontside-illuminated image sensor according to a second embodiment of the present disclosure.

Referring to FIG. 2 and FIG. 1, the frontside-illuminated image sensor 2 of the second embodiment is substantially the same as the frontside-illuminated image sensor 1 of the first embodiment. The difference is only that a plurality of transistors 102 are provided on the base 10 and a source region or a drain region of at least one transistor is the charge storage region 101: there is a metal interconnection layer 14 between the base 10 and the photosensitive unit 11; and the metal interconnection structure 141 of the metal interconnection layer 14 is used to electrically connect to the plurality of transistors 102.

The transistors 102 may include transfer transistors, reset transistors, source-follower transistors, and row select transistors. The source electrode of the transfer transistor is electrically connected to a photosensitive layer through the metal interconnection structure 141, and the drain electrode of the transfer transistor is a floating diffusion region, so the transfer transistor is used to transfer photoelectric charges from a photosensitive layer to the floating diffusion region. The source electrode of the reset transistor is the floating diffusion region, and the drain electrode of the reset transistor is electrically connected to the supply voltage line through the metal interconnection structure 141, so that the reset transistor is used to reset the floating diffusion region to the supply voltage VDD. Through the metal interconnection structure 141, the gate electrode of the source-follower transistor is electrically connected to the floating diffusion region, the source electrode of the source-follower transistor is electrically connected to the supply voltage VDD, and the drain electrode of the source-follower transistor is electrically connected to the source electrode of the row selection transistor. The gate electrode of the row select transistor is electrically connected to the row scan line through metal interconnection structure 141 to output the drain voltage of the source-follower transistor in response to an address signal. The above-mentioned source electrodes and drain electrodes may be exchanged according to the direction of current flow.

In addition, as shown in FIG. 2, the metal interconnection layer 14 has a conductive plug 142. The first end of the conductive plug 142 is connected to a photosensitive layer, and the second end of the conductive plug 142 is electrically connected to the charge storage region 101. Moreover, the first end of the conductive plug 142 is connected to the bottom wall of a photosensitive layer.

In the second embodiment, the photosensitive unit 11 is located above the base 10 rather than flat on the surface of the base 10. Therefore, a large design space may be provided for the charge storage region 101 and the storage capacitor, thereby obtaining a larger full well capacity, improving the high dynamic range and naturally having the design conditions for a global shutter.

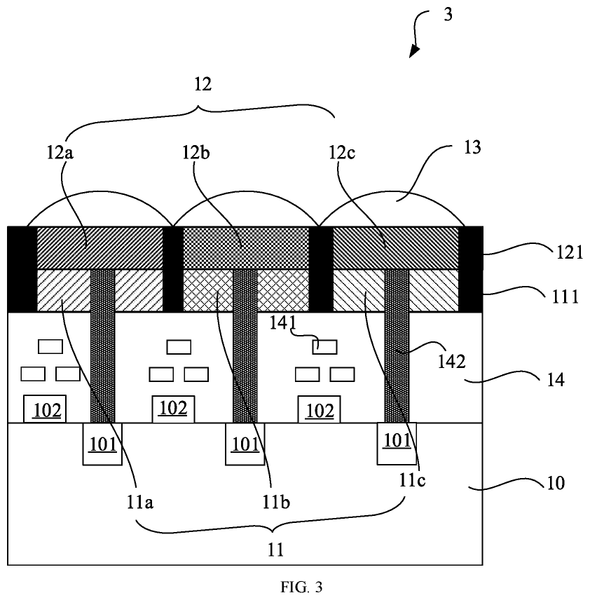

FIG. 3 is a schematic cross-sectional structural diagram of a frontside-illuminated image sensor according to a third embodiment of the present disclosure.

Referring to FIGS. 2 and 3, the frontside-illuminated image sensor 3 of the third embodiment is substantially the same as the frontside-illuminated image sensor 2 of the second embodiment. The difference is only that the first end of the conductive plug 142 is connected to a side wall of the photosensitive layer. Studies have suggested that in the photosensitive layer of GaN-based material containing In, the current flowing in a plane is greater than the current flowing in a direction along a thickness. Therefore, connecting the conductive plug 142 to the side wall of the photosensitive layer may increase the amount of transferred photoelectric charges.

Optionally, the side wall of the photosensitive layer connected to the first end of the conductive plug 142 is close to the first light-shielding structure 111.

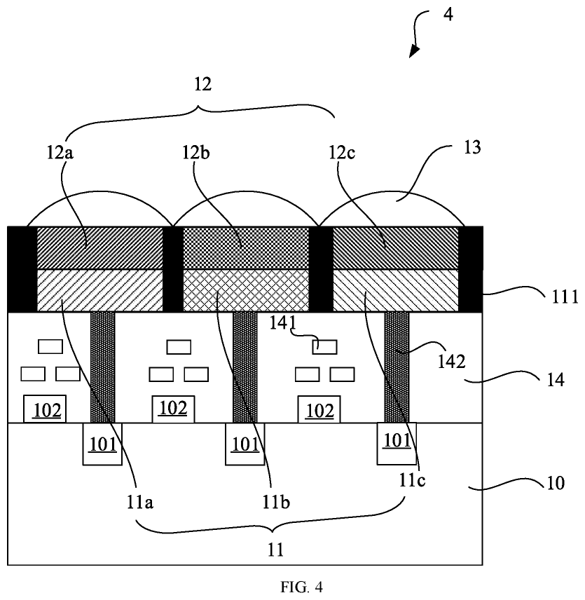

FIG. 4 is a schematic cross-sectional structural diagram for a frontside-illuminated image sensor according to the fourth embodiment of the present disclosure.

Referring to FIGS. 4, 3, 2 and 1, the frontside-illuminated image sensor 4 of the fourth embodiment is substantially the same as the frontside-illuminated image sensors 1, 2, and 3 of the first, second, and third embodiments. The difference is only that the first light-shielding structure 111 is also located between color filter layers for different colors.

The material of the first light-shielding structure 111 is metal molybdenum, metal molybdenum alloy, metal aluminum, metal aluminum alloy, or a black matrix.

Before epitaxially growing the red-light-sensitive layer 11a, the green-light-sensitive layer 11b and the blue-light-sensitive layer 11c on the base 10, the height of the first light-shielding structure 111 may be higher. At this time, the manufacturing of the second light-shielding structure 121 may be omitted.

Compared with the prior art, the present disclosure has the following beneficial effects:

first, the photosensitive unit is located on the base, the color filter unit is at the side of the photosensitive unit away from the base, and the lens structure is at the side of the color filter unit away from the base. In other words, the image sensor is a frontside-illuminated image sensor, which avoids manufacturing structures on the back of the base, therefore, the alignment of the front structure and the back structure is avoided, the process is simple, and the yield is high; secondly, the photosensitive unit is on the base rather than flat on the surface of the base, so the charge storage region and storage capacitor space may be designed to be large enough, thereby obtaining a large full well capacity, enabling an increase in high dynamic range, and naturally meeting the design conditions of a global shutter; third, a photosensitive layer is electrically connected to a charge storage region, an interference caused in a light propagation process is reduced greatly.

Although the present disclosure is disclosed as above, the present disclosure is not limited thereto. Any person skilled in the art may make various changes and modifications without departing from the spirit and scope of the present disclosure, and therefore the scope of protection of the present disclosure shall be subject to the scope defined by the claims.

1. A frontside-illuminated image sensor, comprising:
a base having charge storage regions;
a photosensitive unit above the base, wherein the photosensitive unit comprises photosensitive layers for different colors, and one of the photosensitive layers is electrically connected to one of the charge storage regions;
a color filter unit at a side of the photosensitive unit away from the base, wherein the color filter unit comprises color filter layers for different colors, and one of the color filter layers corresponds to one of the photosensitive layers; and
a lens structure at a side of the color filter unit away from the base.

2. The frontside-illuminated image sensor according to claim 1, wherein, the photosensitive unit comprises a red-light photosensitive layer, a green-light photosensitive layer and a blue-light photosensitive layer, materials of the red-light photosensitive layer, the green-light photosensitive layer and the blue-light photosensitive layer are GaN-based materials containing different proportions of In, to generate photosensitive charges based on wavelengths of received light and store the photosensitive charges in a corresponding charge storage region or not generate photosensitive charges based on the wavelengths of the received light.

3. The frontside-illuminated image sensor according to claim 2, wherein a range of a proportion for In in the red-light photosensitive layer is from 0.4 to 0.6;
a range of a proportion for In in the green-light photosensitive layer is from 0.2 to 0.3; and
a range of a proportion for In in the blue-light photosensitive layer is from 0.01 to 0.1.

4. The frontside-illuminated image sensor according to claim 1, wherein, transistors are provided on the base, and a source region or a drain region of at least one of the transistors is one of the charge storage regions;
there is a metal interconnection layer between the base and the photosensitive unit, and a metal interconnection structure of the metal interconnection layer is used to electrically connect to the transistors.

5. The frontside-illuminated image sensor according to claim 4, wherein, there is a conductive plug in the metal interconnection layer, a first end of the conductive plug is connected to one of the photosensitive layers, and a second end of the conductive plug is electrically connected to one of the charge storage regions.

6. The frontside-illuminated image sensor according to claim 5, wherein the first end of the conductive plug is connected to a side wall of the one of the photosensitive layers.

7. The frontside-illuminated image sensor according to claim 1, wherein there is a first light-shielding structure between the photosensitive layers for different colors, and/or there is a second light-shielding structure between the color filter layers for different colors.

8. The frontside-illuminated image sensor according to claim 7, wherein the material of the first light-shielding structure is metal molybdenum, an alloy of metal molybdenum, metal aluminum or an alloy of metal aluminum, and/or the second light-shielding structure is a black matrix.

9. The frontside-illuminated image sensor according to claim 1, wherein, there is a first light-shielding structure between the photosensitive layers for different colors, and the first light-shielding structure is further between the color filter layers for different colors.

10. The frontside-illuminated image sensor according to claim 9, wherein the material of the first light-shielding structure is metal molybdenum, an alloy of metal molybdenum, metal aluminum, an alloy of metal aluminum or a black matrix.
